(19) United States
(12) Patent Application Publication
(10) Pub. No.: US 2026/0177624 A1
(43) Pub. Date: Jun. 25, 2026

(54) DEVICE AND METHOD WITH BATTERY DEGRADATION STATE ESTIMATION

(71) Applicant: Samsung Electronics Co., Ltd., Suwon-si (KR)

(72) Inventors: Huiyong CHUN, Suwon-si (KR); Jeongsik KO, Suwon-si (KR); Jinho KIM, Suwon-si (KR)

(73) Assignee: Samsung Electronics Co., Ltd., Suwon-si (KR)

(21) Appl. No.: 19/318,011

(22) Filed: Sep. 3, 2025

(30) Foreign Application Priority Data
Dec. 24, 2024 (KR) 10-2024-0194946

(51) Int. Cl. G01R 31/367; G01R 31/36; G01R 31/392

(52) U.S. Cl. CPC G01R 31/367; G01R 31/3646; G01R 31/392

(57) ABSTRACT

A device and method for estimating a degradation state of a battery are provided. A method of estimating degradation state information of a battery mounted on an electronic device includes estimating first degradation state information (current degradation state information) of the battery at a first time point using a trained artificial intelligence (AI) model based on first battery state information of the battery at the first time point. The first battery state information includes a cathode overpotential and an anode overpotential of the battery at the first time point.

### CROSS-REFERENCE TO RELATED APPLICATIONS

This application claims the benefit under 35 USC § 119 (a) of Korean Patent Application No. 10-2024-0194946, filed on Dec. 24, 2024, in the Korean Intellectual Property Office, the entire disclosure of which is incorporated herein by reference for all purposes.

### BACKGROUND

### 1. Field

The following description relates to a device and method with battery degradation state estimation.

### 2. Description of Related Art

Battery degradation refers to the gradual reduction in a battery's storage capacity or power output over time. As degradation progresses, the effective operating time of an electronic device including the battery may decrease.

To provide users with accurate information about a battery degradation state, various technologies have been developed for estimating the battery degradation state. For example, an artificial intelligence (AI) model may be used to estimate the battery degradation state based on usage patterns and operational data.

The above information may be provided as related art to help with the understanding of the disclosure. No arguments or decisions are made as to whether any of the above is applicable as a prior art related to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic device includes a battery configured to supply power; and one or more processors configured to estimate first degradation state information of the battery at a first time point using a trained artificial intelligence (AI) model based on first battery state information of the battery at the first time point, and wherein the first battery state information comprises a cathode overpotential and an anode overpotential of the battery at the first time point.

The cathode overpotential and the anode overpotential may be obtained using a first electrochemical model.

The first battery state information may further include a state of charge, a current, and a voltage of the battery at the first time point.

The first degradation state information may include at least one of anode resistance or cathode capacity of the battery at the first time point.

The first degradation state information may further include an electrode capacity ratio of the battery at the first time point.

The trained AI model may be trained using a training dataset generated by a second electrochemical model.

The training dataset may include one or more set values defined by a user and corresponding battery state data representing one or more of a battery voltage, a battery state of charge, a battery anode overpotential, and a battery cathode overpotential that are generated by the second electrochemical model based on the one or more set values.

The one or more set values may include a set value for each of a battery current, battery anode resistance, battery cathode capacity, and a battery electrode capacity ratio.

The one or more processors may be further configured to update the first electrochemical model based on the first degradation state information; obtain second battery state information of the battery at a second time point subsequent to the first time point using the updated first electrochemical model; and estimate second degradation state information of the battery at the second time point based on the second battery state information using the trained AI model.

The electronic device may further include a display, wherein the one or more processors may be further configured to generate performance data indicating battery performance at the first time point based on the first degradation state information; and display the performance data to a user via the display.

In one general aspect, a processor-implemented method includes estimating first degradation state information of the battery at a first time point using a trained artificial intelligence (AI) model based on first battery state information of the battery at the first time point, wherein the first battery state information includes a cathode overpotential and an anode overpotential of the battery at the first time point.

The method may further include updating the first electrochemical model based on the first degradation state information; obtaining second battery state information of the battery at a second time point subsequent to the first time point using the updated first electrochemical model; and estimating second degradation state information of the battery at the second time point based on the second battery state information using the trained AI model.

The method may further include generating performance data indicating battery performance at the first time point based on the first degradation state information; and visually displaying the performance data to a user via a display of an electronic device.

Other features and aspects will be apparent from the following detailed description, the drawings, and the claims.

### BRIEF DESCRIPTION OF THE DRAWINGS

FIGS. 1 and 2 illustrate respective example electronic devices according to one or more embodiments.

FIG. 3 illustrates an example method of training an artificial intelligence (AI) model according to one or more embodiments.

FIG. 4 illustrates an example method of training an AI model according to one or more embodiments.

FIG. 5 illustrates an example method of estimating degradation state information of a battery according to one or more embodiments.

FIG. 6 illustrates an example method of estimating degradation state information of a battery according to one or more embodiments.

FIG. 7 illustrates an example method of updating an electrochemical model in a battery degradation state information estimating process according to one or more embodiments.

FIG. 8 illustrates an example of accuracy of a method of estimating a battery degradation state information according to one or more embodiments.

FIG. 9 illustrates an example electronic device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment”, and “one or more examples” has a same meaning as “in one or more embodiments”).

Throughout the specification, when a component, element, or layer is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C” (e.g., each phrase may include any one of the respective items alone, all of the items listed together, and all possible combinations thereof), and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

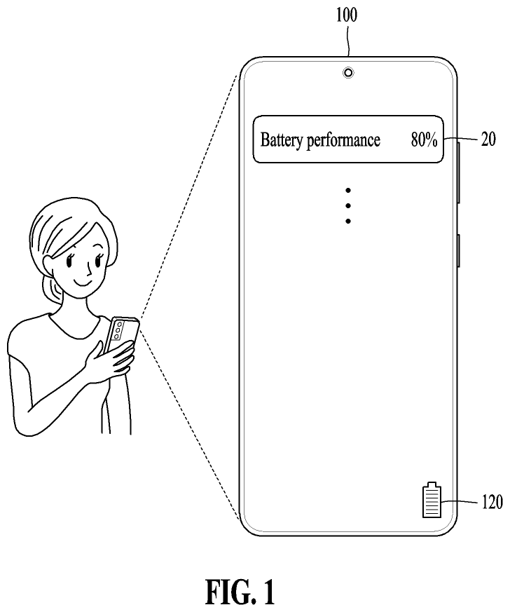

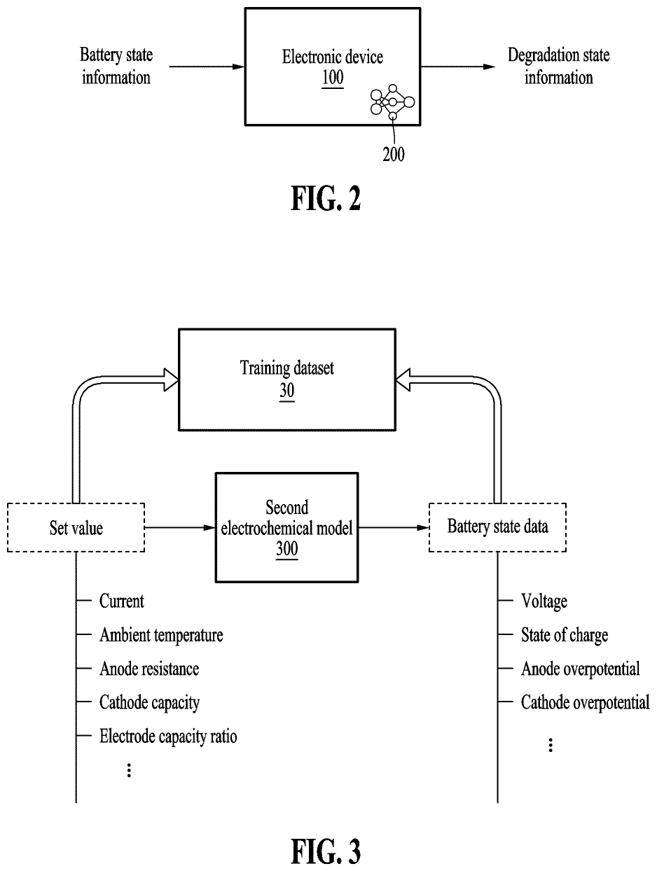

FIGS. 1 and 2 illustrate respective example electronic devices according to one or more embodiments.

Referring to FIGS. 1 and 2, according to an example, an electronic device 100 may include a battery 120 configured to supply power to various components of the electronic device 100, such as a processor, a communication module, and a display module. For example, the electronic device 100 may be a smartphone, tablet, smart watch, laptop, and/or home appliance (e.g., a portable television (TV) or a portable speaker).

The electronic device 100 may generate performance data 20 (e.g., a performance score) that provides information on current performance of the battery 120. The electronic device 100 may visually provide the performance data 20 to a user via a display included in the electronic device 100.

The electronic device 100 may generate the performance data 20 based on degradation state information of the battery 120. The electronic device 100 may estimate the degradation state information of the battery 120 using an artificial intelligence (AI) model 200 (e.g., a pre-trained neural network), which processes the battery state information of the battery 120. The AI model 200 may be implemented as an on-device model stored in a memory of the electronic device 100, but is not limited thereto.

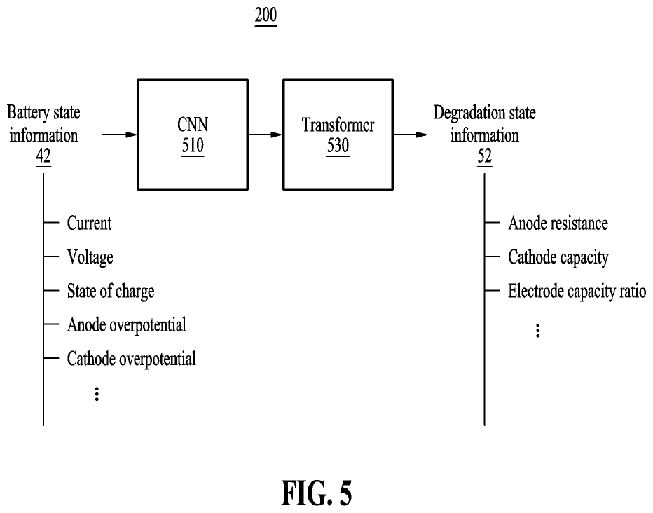

The method of estimating the degradation state information of the battery 120 will be described in detail with reference to FIGS. 5 through 7.

FIG. 3 illustrates an example method of training an AI model according to one or more embodiments.

Referring to FIG. 3, according to an example, an AI model (e.g., the AI model 200 of FIG. 2) may be a pre-trained deep learning model trained using a training dataset 30. The training dataset 30 may be generated by an electronic device (e.g., the electronic device 100 of FIG. 1 or FIG. 2) or another electronic device, such as a server. For convenience, a device used to generate the training dataset will hereinafter be referred to as a “training device.”

The training device may include a first electrochemical model (not shown) and a second electrochemical model 300. The training device may use the second electrochemical model 300 to generate the training dataset 30. Herein, the second electrochemical model 300 may refer to an electrochemical model used during a training phase of the AI model, and the first electrochemical model may refer to an electrochemical model used during an inference phase of the AI model. The first and second electrochemical models may be identical or may differ.

An electrochemical model (e.g., a polarization model or a pseudo two-dimensional (P2P) model) may refer to a model that mathematically or physically represents operating mechanisms of a battery. Such a model may use various equations, such as the Butler-Volmer equation and Nernst equation, to describe the operating mechanisms of the battery.

The training device may obtain battery state data corresponding to one or more set values using the second electrochemical model 300. Herein, the one or more set values may be a specific value input to the second electrochemical model 300 to obtain/derive the corresponding battery state data. Examples of the set values may include a current of a battery, ambient temperature, anode resistance of a battery, cathode capacity of a battery, and/or an electrode capacity ratio of a battery. The set values may be input (or set) to the training device by a user. During the training process, some set values (e.g., current) may be used as input data for the AI model, while other set values (e.g., anode resistance, cathode capacity, and/or electrode capacity ratio) may be used as ground truth labels.

The battery state data may include one or more of: a voltage, state of charge, anode overpotential, and/or cathode overpotential of the battery. Some of the battery state data may be used as input data for the AI model during the training process. For example, the voltage, state of charge, anode overpotential, and cathode overpotential may serve as input data for the AI model.

The training device may iteratively adjust the set values to generate the training dataset. For example, during one data generation cycle, the training device may set the current to “1 mA,” the ambient temperature to “20° C.,” the anode resistance to “10 mΩ,” and the electrode capacity ratio to “1.1:1 (anode:cathode)”. In a subsequent data generation cycle, the training device may set the current to “1.3 mA,” the ambient temperature to “30° C.,” the anode resistance to “5 mΩ,” and the electrode capacity ratio to “1.05:1 (anode:cathode)”. For each cycle, the training device may generate the battery state data corresponding to the set values using the second electrochemical model 300.

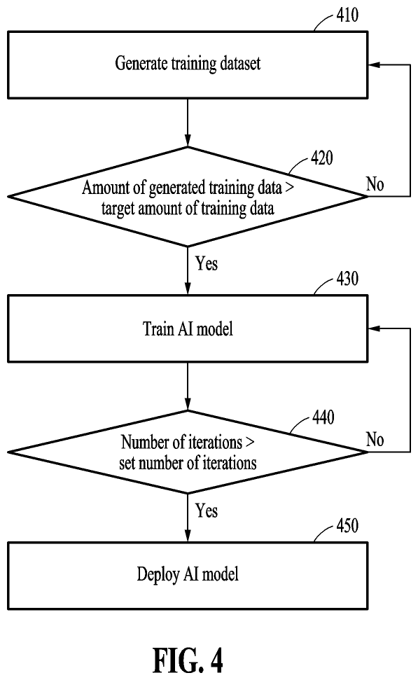

FIG. 4 illustrates another example method of training an AI model according to one or more embodiments.

Referring to FIG. 4, according to an example, the training device may use a dataset that satisfies a predetermined target amount of training data to train the AI model (e.g., the AI model 200 of FIG. 2). Improved AI model performance may be achieved as the training dataset increases in quantity and diversity.

In operation 410, the training device may generate a training dataset (e.g., the training dataset 30 of FIG. 3).

In operation 420, the training device may determine whether the amount of generated training data satisfies the target amount of training data. The target amount of training data may be set by the user. The target amount of training data may be set in various ways. For example, the target amount of training data may be defined as a size of the training data (e.g., 10 terabytes).

When the amount of generated training data is below the target amount of training data, the training device may modify the set values (e.g., the set values described in FIG. 3), and generate the battery state data corresponding to the modified set values.

In operation 430, when the amount of generated training data reaches or exceeds the target amount of training data, the training device may begin training the AI model using the accumulated training data. The training device may train the AI model using supervised learning based on the generated training data.

According to an example, prior to the supervised learning, the training device may train the AI model through contrastive learning (e.g., supervised contrastive learning) to pre-train the AI model. This two-phase training approach-contrastive learning followed by supervised learning—can enhance the overall performance of the trained AI model of the one or more embodiments.

In operation 440, the training device may determine whether the number of iterations of supervised learning satisfies a set number of iterations (e.g., 100,000 iterations). When the number of iterations of supervised learning is below the set number of iterations, the training device may additionally train the AI model.

In operation 450, when the number of iterations of supervised learning reaches or exceeds the set number of iterations, the training device may deploy the AI model (e.g., the trained AI model). For example, the AI model may be stored in a memory of an electronic device (e.g., the electronic device 100 of FIG. 1 or FIG. 2). According to an example, the deployment of the AI model may be performed by a device other than the training device.

FIG. 5 illustrates an example method of estimating degradation state information of a battery according to one or more embodiments.

Referring to FIG. 5, according to an example, the AI model 200 may estimate degradation state information 52 of a battery (e.g., the battery 120 of FIG. 1) based on battery state information 42 of the battery obtained during the inference phase. The AI model 200 may include a convolutional neural network (CNN) 510 and a transformer 530, but this is merely an example and the range of the present disclosure is not limited thereto. The CNN 510 may extract feature information (e.g., local feature) from the battery state information 42. The transformer 530 may generate the degradation state information 52 based on the extracted feature information.

The battery state information 42 may include data indicating the state information of the battery. For example, the battery state information 42 may include current, voltage, state of charge, anode overpotential, and/or cathode overpotential of the battery at each time point. The battery state information 42 may be obtained directly from sensors embedded in an electronic device (e.g., the electronic device 100 of FIG. 1 or FIG. 2) in which the battery is mounted, or may be derived from the first electrochemical model of the battery. For example, the current and the voltage may be measured using sensors, while the state of charge, the anode overpotential, and the cathode overpotential may be obtained using the first electrochemical model. The first electrochemical model may refer to an electrochemical model used during the inference phase, as described above. The first electrochemical model may be stored in a memory of the electronic device.

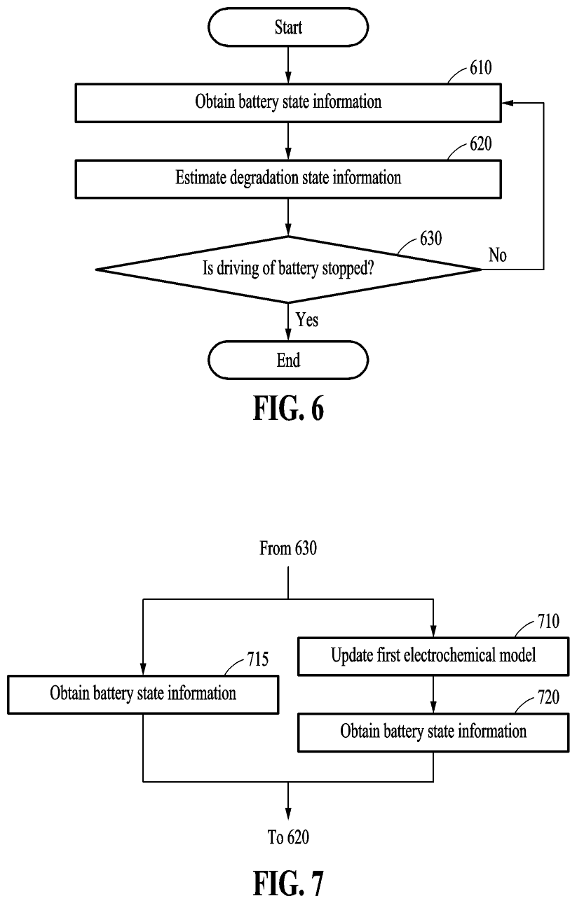

FIG. 6 illustrates an example method of estimating degradation state information of a battery according to one or more embodiments.

Referring to FIG. 6, according to an example, an electronic device (e.g., the electronic device 100 of FIG. 1 or FIG. 2) may estimate degradation state information (e.g., the degradation state information 52 of FIG. 5) of a battery (e.g., the battery 120 of FIG. 1) while the battery is supplying power to the electronic device 100.

In operation 610, the electronic device may obtain battery state information (e.g., the battery state information 42 of FIG. 5) of the battery.

In operation 620, the electronic device may estimate the degradation state information of the battery based on the obtained battery state information.

In operation 630, the electronic device may determine whether the battery is currently in use (i.e., “driving”). For example, when the electronic device is powered by a power source other than the battery (e.g., when the battery is charging), the electronic device may determine that the driving of the battery is stopped or that the battery is not driving.

When the battery is currently being driven, the electronic device may obtain the battery state information of the battery at a next estimation time point (time point for estimation), and generate the degradation state information of the battery at the next estimation time point based on the obtained battery state information. The time point of obtaining the battery state information and/or the time point of obtaining the degradation state information may be based on the settings of the electronic device. For example, the electronic device may obtain the battery state information at set intervals, and estimate the degradation state information based on the obtained battery state information.

FIG. 7 illustrates an example method of updating an electrochemical model during a battery degradation estimating process according to one or more embodiments.

Referring to FIG. 7, according to an example, an electronic device (e.g., the electronic device 100 of FIG. 1 or FIG. 2), in which a battery (e.g., the battery 120 of FIG. 1) is installed, may update a first electrochemical model used to obtain battery state information (e.g., the battery state information 42 of FIG. 5). Operation 715 may be performed in parallel with operation 710 or 720.

In operation 710, the electronic device may update the first electrochemical model to obtain the battery state information of the battery at the next estimation time point. For example, the electronic device may update one or more equations of the first electrochemical model. The electronic device may use degradation state information (e.g., the degradation state information 52 of FIG. 5) of the battery obtained at a previous estimation time point to update the first electrochemical model.

For example, the first electrochemical model may include an equation related to the anode overpotential, which may be shown as Equation 1 below, for example.

$$η = {ϕ}_{s} - {ϕ}_{e} - {U}_{ocp} - F \cdot {R}_{film} \cdot {j}_{a} \qquad Equation 1$$

In Equation 1, η may be an anode overpotential, φₛ may be a potential of an anode active material, φₑ may be a potential of an electrolyte, U_{ocp} may be an open circuit potential, F may be a Faraday constant, R_{film} may be anode resistance, and j may be a current density between the anode active material and the electrolyte.

Referring to Equation 1, according to an example, the electronic device may update Equation 1 based on the anode resistance of the battery obtained at the previous estimation time point, to obtain the anode overpotential at a next estimation time point. For example, when the anode resistance obtained at the previous estimation time point is 0.5 mΩ, the electronic device may update f film of Equation 1 based on the value “0.5 mΩ,” and obtain the anode overpotential at the next estimation time point using the updated Equation 1.

In operation 715, the electronic device may obtain battery state information directly from a sensor. For example, the electronic device may obtain a current and a voltage from the sensor.

In operation 720, the electronic device may derive battery state information using the updated first electrochemical model. For example, the electronic device may derive the state of charge, the anode overpotential, and the cathode overpotential using the updated first electrochemical model.

According to an example, the first electrochemical model may be updated at each estimation time point to enhance the accuracy of the derived battery state information. By using this derived battery state information, the electronic device may estimate the degradation state of a battery with high precision.

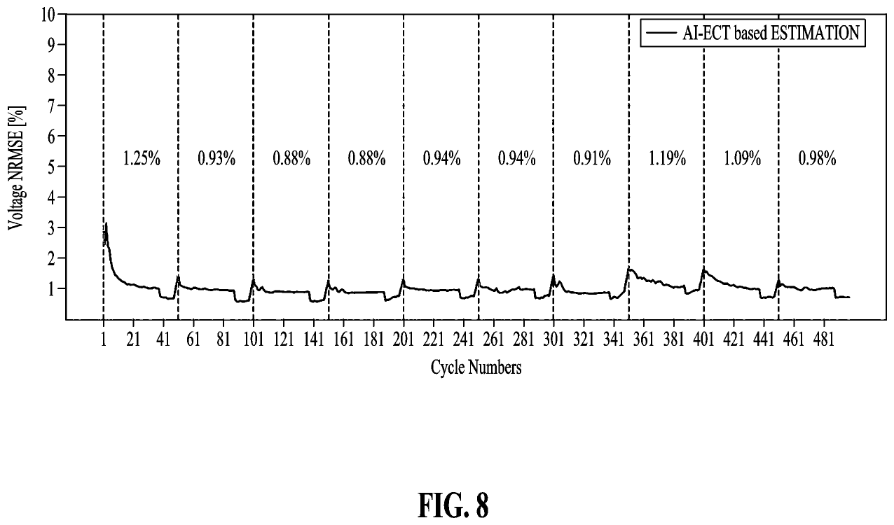

FIG. 8 illustrates an example of accuracy of a method of estimating a battery degradation state information according to one or more embodiments.

Referring to FIG. 8, a voltage normalized root mean square error (NRMSE), which indicates an error between the estimated value generated by the method of estimating the battery degradation state information according to one or more embodiments and an actual value, may be approximately 1%. This demonstrates that the method of estimating the battery degradation state information can provide degradation state information with high accuracy.

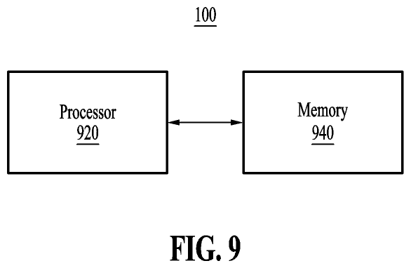

FIG. 9 illustrates an example electronic device according to one or more embodiments.

Referring to FIG. 9, the electronic device 100 may include one or more processors 920 and a memory 940.

The memory 940 may store instructions (or programs) executable by the one or more processors 920. For example, the instructions may execute operations of the one or more processors 920 and/or operations of components included in the one or more processors 920.

The memory 940 may include one or more computer-readable storage media, such as non-volatile storage elements (e.g., a magnetic hard disk, optical disc, floppy disc, flash memory, electrically programmable memory (EPROM), and electrically erasable and programmable memory (EEPROM)).

The memory 940 may be a non-transitory medium. The term “non-transitory” may indicate that a storage medium is not embodied in a carrier wave or a propagated signal. However, the term “non-transitory” should not be interpreted to mean that the memory 940 is physically immobile.

The one or more processors 920 may process data stored in the memory 940. The one or more processors 920 may execute computer-readable code (e.g., software) and instructions stored in the memory 940.

The one or more processors 920 may each be a hardware-implemented data processing device comprising circuits physically structured to perform designated operations. These operations may include, for example, executing code or instructions included in a program.

The hardware-implemented data processing device may include, for example, a microprocessor, a central processing unit (CPU), a processor core, a multi-core processor, a multiprocessor, an application-specific integrated circuit (ASIC), and a field-programmable gate array (FPGA).

The one or more processors 920 may include a main processor (e.g., a CPU or an application processor) and an auxiliary processor (e.g., a communication processor, a neural processing unit (NPU), and/or a graphics processing unit (GPU)).

The one or more processors 920 may execute, individually or collectively, code, instructions, or applications stored in the memory 940 to enable the electronic device 100 to perform various operations.

An electronic device according to an example may include a battery configured to supply power, at least one processor, and at least one memory configured to store instructions. The instructions, in response to being executed individually or collectively by the at least one processor, may cause the electronic device to estimate first degradation state information (current degradation state information) of the battery at a first time point using a trained AI model based on first battery state information of the battery at the first time point. The first battery state information may include a cathode overpotential and an anode overpotential of the battery at the first time point.

Each of the cathode overpotential and the anode overpotential may be obtained using a first electrochemical model.

The first battery state information may further include a state of charge, a current, and a voltage of the battery at the first time point.

The first degradation state information may include at least one of anode resistance or cathode capacity of the battery at the first time point.

The first degradation state information may further include an electrode capacity ratio of the battery at the first time point.

The trained AI model may be trained based on a training dataset generated using a second electrochemical model (battery electrochemical model).

The training dataset may include at least one set value that is set by a user, and a battery voltage, a battery state of charge, a battery anode overpotential, and a battery cathode overpotential generated by the second electrochemical model based on the at least one set value.

The at least one set value may include a set value of each of a battery current, battery anode resistance, battery cathode capacity, and a battery electrode capacity ratio.

Each of the battery voltage, the battery state of charge, the battery anode overpotential, and the battery cathode overpotential may be used as input data for inference during a training phase of the trained AI model.

The battery current may be used as input data for inference during the training phase, and each of the anode resistance, the battery cathode capacity, and the battery electrode capacity ratio may be used as ground truth during the training phase.

The instructions, in response to being executed individually or collectively by the at least one processor, may cause the electronic device to update the first electrochemical model based on the first degradation state information. The instructions, in response to being executed individually or collectively by the at least one processor, may cause the electronic device to obtain second battery state information of the battery at a second time point that is after the first time point using the updated first electrochemical model. The instructions, in response to being executed individually or collectively by the at least one processor, may cause the electronic device to estimate second degradation state information of the battery at the second time point based on the second battery state information using the trained AI model.

The electronic device may further include a display. The instructions, in response to being executed individually or collectively by the at least one processor, may cause the electronic device to generate performance data for providing information on performance of the battery at the first time point based on the first degradation state information. The instructions, in response to being executed individually or collectively by the at least one processor, may cause the electronic device to visually provide the performance data to the user through the display.

A method of estimating degradation state information of a battery mounted on an electronic device according to an example may include estimating first degradation state information (current degradation state information) of the battery at a first time point using a trained AI model based on first battery state information of the battery at the first time point. The first battery state information may include a cathode overpotential and an anode overpotential of the battery at the first time point.

Each of the cathode overpotential and the anode overpotential may be obtained using a first electrochemical model.

The first battery state information may further include a state of charge, a current, and a voltage of the battery at the first time point.

The first degradation state information may include at least one of anode resistance or cathode capacity of the battery at the first time point.

The first degradation state information may further include an electrode capacity ratio of the battery at the first time point.

The trained AI model may be trained based on a training dataset generated using a second electrochemical model (battery electrochemical model).

The training dataset may include at least one set value that is set by a user, and a battery voltage, a battery state of charge, a battery anode overpotential, and a battery cathode overpotential generated by the second electrochemical model based on the at least one set value.

The at least one set value may include a set value of each of a battery current, battery anode resistance, battery cathode capacity, and a battery electrode capacity ratio.

Each of the battery voltage, the battery state of charge, the battery anode overpotential, and the battery cathode overpotential may be used as input data for inference during a training phase of the trained AI model.

The battery current may be used as input data for inference during the training phase, and each of the anode resistance, the battery cathode capacity, and the battery electrode capacity ratio may be used as ground truth during the training phase.

The method may further include updating the first electrochemical model based on the first degradation state information. The method may further include obtaining second battery state information of the battery at a second time point that is after the first time point using the updated first electrochemical model. The method may further include estimating second degradation state information of the battery at the second time point based on the second battery state information using the trained AI model.

The method may further include generating performance data for providing information on performance of the battery at the first time point based on the first degradation state information. The method may further include visually providing the performance data to the user through a display of the electronic device.

The electronic devices, processors, memory, storage devices, electronic device 100, neural network 500, transformer 530, processors 920, memory 940, and other apparatuses, devices, models, and components described herein with respect to FIGS. 1-9 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An electronic device comprising:
a battery configured to supply power; and
one or more processors configured to:
estimate first degradation state information of the battery at a first time point using a trained artificial intelligence (AI) model based on first battery state information of the battery at the first time point, and
wherein the first battery state information comprises a cathode overpotential and an anode overpotential of the battery at the first time point.

2. The electronic device of claim 1, wherein the cathode overpotential and the anode overpotential are obtained using a first electrochemical model.

3. The electronic device of claim 1, wherein the first battery state information further comprises a state of charge, a current, and a voltage of the battery at the first time point.

4. The electronic device of claim 1, wherein the first degradation state information comprises at least one of anode resistance or cathode capacity of the battery at the first time point.

5. The electronic device of claim 4, wherein the first degradation state information further comprises an electrode capacity ratio of the battery at the first time point.

6. The electronic device of claim 1, wherein the trained AI model is trained using a training dataset generated by a second electrochemical model.

7. The electronic device of claim 6, wherein the training dataset comprises one or more set values defined by a user and corresponding battery state data representing one or more of a battery voltage, a battery state of charge, a battery anode overpotential, and a battery cathode overpotential that are generated by the second electrochemical model based on the one or more set values.

8. The electronic device of claim 7, wherein the one or more set values comprise a set value for each of a battery current, battery anode resistance, battery cathode capacity, and a battery electrode capacity ratio.

9. The electronic device of claim 2, wherein the one or more processors are further configured to:
update the first electrochemical model based on the first degradation state information;
obtain second battery state information of the battery at a second time point subsequent to the first time point using the updated first electrochemical model; and
estimate second degradation state information of the battery at the second time point based on the second battery state information using the trained AI model.

10. The electronic device of claim 1, further comprising:
a display,
wherein the one or more processors are further configured to:
generate performance data indicating battery performance at the first time point based on the first degradation state information; and
display the performance data to a user via the display.

11. A processor-implemented method, the method comprising:
estimating first degradation state information of the battery at a first time point using a trained artificial intelligence (AI) model based on first battery state information of the battery at the first time point,
wherein the first battery state information comprises a cathode overpotential and an anode overpotential of the battery at the first time point.

12. The method of claim 11, wherein the cathode overpotential and the anode overpotential are obtained using a first electrochemical model.

13. The method of claim 11, wherein the first battery state information further comprises a state of charge, a current, and a voltage of the battery at the first time point.

14. The method of claim 11, wherein the first degradation state information comprises at least one of anode resistance or cathode capacity of the battery at the first time point.

15. The method of claim 14, wherein the first degradation state information further comprises an electrode capacity ratio of the battery at the first time point.

16. The method of claim 11, wherein the trained AI model is trained using a training dataset generated by a second electrochemical model.

17. The method of claim 16, wherein the training dataset comprises one or more set values defined by a user and corresponding battery state data representing one or more of a battery voltage, a battery state of charge, a battery anode overpotential, and a battery cathode overpotential that are generated by the second electrochemical model based on the at least one set value.

18. The method of claim 17, wherein the one or more set values comprise a set value for each of a battery current, battery anode resistance, battery cathode capacity, and a battery electrode capacity ratio.

19. The method of claim 12, further comprising:
updating the first electrochemical model based on the first degradation state information;
obtaining second battery state information of the battery at a second time point subsequent to the first time point using the updated first electrochemical model; and
estimating second degradation state information of the battery at the second time point based on the second battery state information using the trained AI model.

20. The method of claim 11, further comprising:
generating performance data indicating battery performance at the first time point based on the first degradation state information; and
visually displaying the performance data to a user via a display of an electronic device.
